(19) United States
(12) Patent Application Publication
(10) Pub. No.: US 2024/0038811 A1
(43) Pub. Date: Feb. 1, 2024

(54) PHOTOELECTRIC CONVERSION APPARATUS AND EQUIPMENT

(71) Applicant: CANON KABUSHIKI KAISHA, Tokyo (JP)

(72) Inventors: SHO SUZUKI, Tokyo (JP); NAO NAKATSUJI, Kanagawa (JP)

(21) Appl. No.: 18/360,651

(22) Filed: Jul. 27, 2023

(30) Foreign Application Priority Data
Aug. 1, 2022 (JP) 2022-122765

(51) Int. Cl. H01L 27/146

(52) U.S. Cl. CPC H01L 27/14634; H01L 27/14636; H01L 27/1469

(57) ABSTRACT

A photoelectric conversion apparatus includes a first member in a first semiconductor layer, a second member in a second semiconductor layer, and a third member in a third semiconductor layer. In the first semiconductor layer, a first member includes a photoelectric conversion unit and a transfer transistor configured to transfer an electric charge generated in the photoelectric conversion unit. In the second semiconductor layer, a second member includes a readout circuit configured to output a signal based on the electric charge transferred from the transfer transistor. In the third member includes a signal processing circuit configured to process the signal. The first member, the second member, and the third member are stacked, and a source region or a drain region of a transistor forming the readout circuit includes a salicide structure.

### BACKGROUND

### Technical Field

The aspect of the embodiments relates to a photoelectric conversion apparatus and equipment.

### Description of the Related Art

In the development field of photoelectric conversion apparatuses represented by, for example, an image capturing apparatus, backside irradiation type sensors and stacked type sensors, in which a substrate for a sensor and a substrate for a signal processing circuit are stacked, have been proposed to achieve, for example, reduction in size, higher sensitivity, multi-functionality of the photoelectric conversion apparatuses. International Patent Publication No. WO 2020/262643 discusses a configuration in which a first semiconductor layer and a second semiconductor layer are stacked. In the first semiconductor layer, a photoelectric conversion unit and a transfer transistor are disposed, and in the second semiconductor layer, a readout circuit including an amplification transistor, a reset transistor, and a selection transistor are disposed. With this configuration discussed in International Patent Publication No. WO 2020/262643, a higher pixel density is achieved. International Patent Publication No. WO 2020/262643 also discusses a technique of forming a silicide in each of the gate of the selection transistor and the gate of the amplification transistor, to reduce a resistance value.

### SUMMARY

According to an aspect of the embodiments, a photoelectric conversion apparatus includes a first member including a photoelectric conversion unit and a transfer transistor in a first semiconductor layer, the transfer transistor being configured to transfer an electric charge generated in the photoelectric conversion unit, a second member including a readout circuit in a second semiconductor layer, the readout circuit being configured to output a signal based on the electric charge transferred from the transfer transistor, and a third member including a signal processing circuit in a third semiconductor layer, the signal processing circuit being configured to process the signal, wherein a first wiring structure included in the first member is disposed between the first semiconductor layer and the second semiconductor layer, and a second wiring structure included in the second member and a third wiring structure included in the third member are stacked between the second semiconductor layer and the third semiconductor layer, wherein the readout circuit is configured to output the signal from the second member to the third member via an output line disposed in the second wiring structure, wherein a source region or a drain region of a transistor forming the readout circuit includes a salicide structure, and wherein a diffusion prevention layer is disposed between the first semiconductor layer and the second semiconductor layer, the diffusion prevention layer preventing diffusion of metal included in the salicide structure.

Further features of the disclosure will become apparent from the following description of exemplary embodiments with reference to the attached drawings.

### BRIEF DESCRIPTION OF THE DRAWINGS

FIG. 1 is a diagram illustrating a configuration of a photoelectric conversion apparatus according to a first exemplary embodiment.

FIG. 2 is a circuit diagram illustrating a schematic configuration of a photoelectric conversion unit and a readout circuit according to the first exemplary embodiment.

FIG. 3 is a schematic cross-sectional view illustrating a configuration of the photoelectric conversion apparatus according to the first exemplary embodiment.

FIGS. 4A to 4C are cross-sectional views illustrating a manufacturing method of the photoelectric conversion apparatus according to the first exemplary embodiment.

FIGS. 5A and 5B are cross-sectional views illustrating a manufacturing method of the photoelectric conversion apparatus according to the first exemplary embodiment.

FIG. 6 is a cross-sectional view illustrating a manufacturing method of the photoelectric conversion apparatus according to the first exemplary embodiment.

FIGS. 7A and 7B are cross-sectional views illustrating a manufacturing method of a photoelectric conversion apparatus according to a second exemplary embodiment.

FIGS. 8A and 8B are cross-sectional views illustrating a manufacturing method of the photoelectric conversion apparatus according to the second exemplary embodiment.

FIG. 9 is a schematic cross-sectional view illustrating a configuration of a photoelectric conversion apparatus according to a third exemplary embodiment.

FIGS. 10A to 10C are diagrams illustrating a configuration of equipment according to a fourth exemplary embodiment.

### DESCRIPTION OF THE EMBODIMENTS

In terms of a technique for reducing a source/drain resistance of transistors forming a readout circuit, the discussion in International Patent Publication No. WO 2020/262643 may be insufficient. The aspect of the embodiments is directed to providing a photoelectric conversion apparatus capable of high-speed driving with a low resistance than in comparison with the transistors included in the readout circuit discussed in International Patent Publication No. WO 2020/262643.

The following exemplary embodiments are intended to embody the technical idea of the disclosure and is not intended to limit the disclosure. Some of the sizes and positional relationships of members illustrated in the drawings are exaggerated for clarity of description. In the following description, the same components are denoted by the same reference numerals, and the redundant descriptions may be omitted. Components described in some exemplary embodiments can be replaced or combined with components described in other exemplary embodiments if there are no technical issues.

In the following description, the terms which designate specific directions or positions, for example, “up”, “down”, “right”, “left”, and other terms including such terms, are used as needed. These terms are used for clear understanding of the disclosure with reference to the drawings, and the technical scope of the disclosure is not limited by the meanings of the terms. In other words, for example, the components that are upside down also belong to the technical scope of the disclosure.

In the following exemplary embodiments, a photoelectric conversion apparatus and equipment including the photoelectric conversion apparatus will be described. Examples of the photoelectric conversion apparatus include an image capturing apparatus, a distance-measuring apparatus, and a photometric apparatus. The distance-measuring apparatus is, for example, an apparatus that measures a distance using focus detection or Time of Flight (ToF). The photometric apparatus is, for example, an apparatus for measuring the amount of incident light.

A conductivity type of a semiconductor region, a conductivity type of a well, and an implanted dopant to be described in the following exemplary embodiments are merely examples, and are not limited only to the conductivity types and the dopant described in the exemplary embodiments. The conductivity types and the dopant described in the exemplary embodiments can be appropriately changed, and the potential of each of the semiconductor region and the well can be changed appropriately according to the change.

Conductivity types of transistors described in the following exemplary embodiments are merely examples, and are not limited only to the conductivity types described in the exemplary embodiments. The conductivity types described in the exemplary embodiments can be changed as appropriate. In the following description, for example, an n-type semiconductor is described as a first-conductivity-type semiconductor, and a p-type semiconductor is described as a second-conductivity-type semiconductor. However, these conductivity types can be reversed.

In the following exemplary embodiments, a description will be given of a connection between circuit elements. In this case, even if another element is between elements of interest, unless otherwise described, the elements of interest are treated as being electrically connected to each other. An example of such a case is that an element A is connected to one node of a capacitor element C, which has a plurality of nodes, and an element B is connected to the other node of the capacitor element C. Even in this case, unless otherwise described, the element A and the element B are treated as being electrically connected to each other.

Metal members, such as wires and pads, described in the exemplary embodiments can be composed of a metal element, or can be composed of a mixture of metals (alloy). For example, a wire described as a copper wire can be composed of copper, or can be composed primarily of copper and can also contain other components. For example, a pad connected to an external terminal can be composed of aluminum, or can be composed primarily of aluminum and can also contain other components. The materials of the copper wire and the aluminum pad are merely examples and can be replaced with various types of metal.

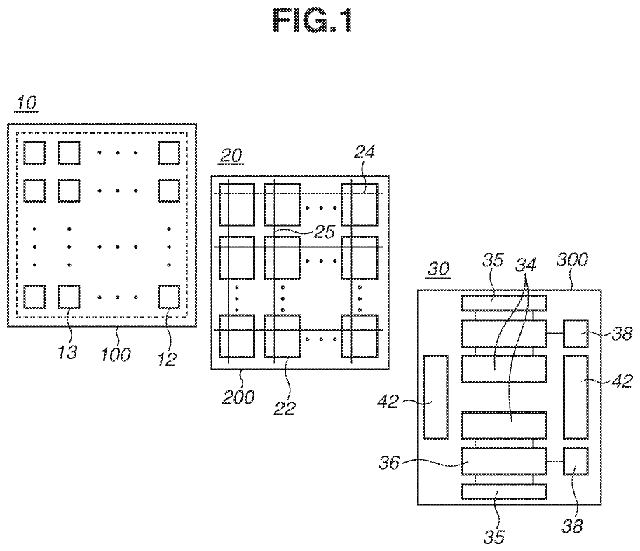

FIG. 1 illustrates a configuration example of a photoelectric conversion apparatus according to a first exemplary embodiment. The photoelectric conversion apparatus is an image capturing apparatus having a three-dimensional structure in which three substrates including a first member 10, a second member 20, and a third member 30, are bonded together. The first member 10, the second member 20, and the third member 30 are stacked in this order. Specifically, the second member 20 is stacked on the first member 10, and the third member 30 is stacked on the second member 20.

The first member 10 includes a plurality of sensor units 12 for photoelectric conversion. A semiconductor layer (first semiconductor layer) 100 of the first member 10 has a sensor region 13. The plurality of sensor units 12 is arranged in a matrix in the sensor region 13. Each of the sensor units 12 is also referred to as a “pixel”.

The second member 20 includes readout circuits 22 in a semiconductor layer (second semiconductor layer) 200. The readout circuits 22 are each configured to output signals based on signal charges output from the sensor units 12. For example, each of the readout circuits 22 is shared between corresponding four of the sensor units 12. The second member 20 also includes a plurality of drive lines 24 elongated in a row direction, and a plurality of output lines 25 elongated in a column direction. The drive lines 24 are control lines for controlling transistors included in the readout circuit 22. For example, the drive lines 24 are electrically connected to the gates of reset transistors and the gates of selection transistors. The output lines 25 are wires that input output signals from the sensor units 12 to the third member 30.

The third member 30 includes a logic circuit in a semiconductor layer (third semiconductor layer) 300. The logic circuit is configured to process signals output from the second semiconductor layer 200. The logic circuit includes, for example, vertical scanning circuits 42, column signal processing circuits 34, horizontal scanning circuits 35, a memory 36, and output circuits 38.

The horizontal scanning circuits 35 output signals that have been output from the sensor units 12 and stored in the memory 36 to the outside of the photoelectric conversion apparatus via the output circuits 38. In the logic circuit, for example, a low-resistance region including a silicide structure formed by a self-aligned silicide (salicide) process can be formed on surfaces of impurity diffusion regions that is in contact with source and drain regions of the transistors. The salicide process will be described in detail below.

The vertical scanning circuits 42 sequentially selects a plurality of the sensor units 12 row by row, for example. The column signal processing circuits 34 perform correlated double sampling (CDS) processing on signals output from the sensor units 12 included in the row selected by the vertical scanning circuit 42, for example. Each of the column signal processing circuits 34 includes an analog-to-digital (AD) conversion circuit that converts signals (analog signal) output from amplification transistors into digital signals, for example. The memory 36 holds pieces of data based on the amount of light received by the respective sensor units 12. The horizontal scanning circuits 35 sequentially output the pieces of data held in the memory 36 to the outside of the photoelectric conversion apparatus via the output circuits 38, for example. A control circuit (not illustrated) controls driving of, for example, blocks, which are the vertical scanning circuits 42, the column signal processing circuits 34, and the horizontal scanning circuits 35, in the logic circuit.

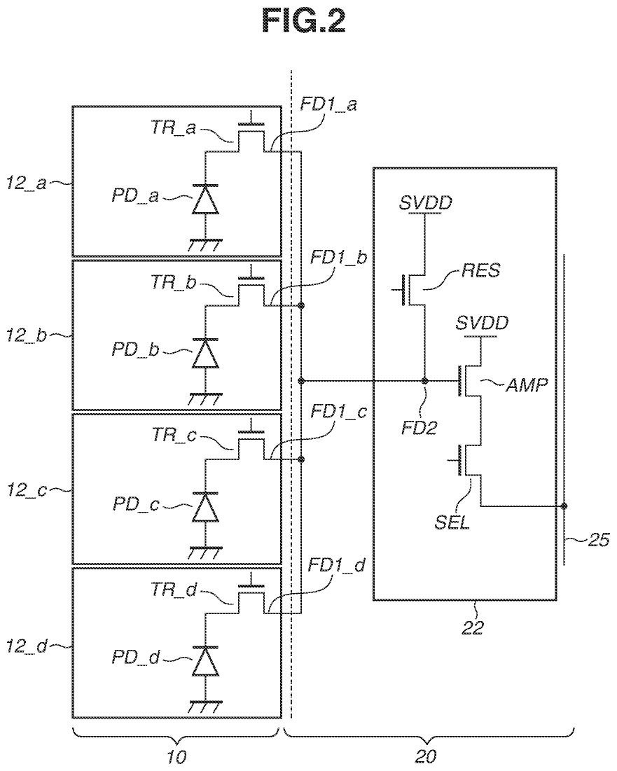

FIG. 2 is a circuit diagram illustrating a configuration example of the sensor units 12 in the first member 10, and a configuration example of the readout circuit 22 in the second member 20. A description will be given of a case where four sensor units, which are sensor units 12_a to 12_d, share one readout circuit, which is the readout circuit 22, as illustrated in FIG. 2. The term “share” used here indicates that output signals from the four sensor units 12_a to 12_d are input to a common readout circuit, i.e., the readout circuit 22. In the description below, when a feature that is common to the sensor units 12_a to 12_d is described, the sensor units 12_a to 12_d are sometimes collectively referred to as the sensor unit 12.

Each of the sensor units 12 includes a photodiode PD, a transfer transistor TR that is electrically connected to the photodiode PD, and a first floating diffusion (FD) node FD1 as a part of the FD, for example. Reference signs “a” to “d” are added to the ends of reference numerals denoting the members of the photodiodes and transfer gates in the respective sensor units 12.

The readout circuit 22 includes a second FD node FD2 as another part of the FD that temporarily holds an electric charge output from the photodiode PD via the transfer transistor TR. Four first FD nodes FD1_a to FD1_d are connected to the second FD node FD2. The second FD node FD2 is an input node of an amplification transistor AMP.

The photodiode PD as the photoelectric conversion unit is an element that generates an electric charge based on the amount of received light.

The cathode of the photodiode PD is electrically connected to the source of the transfer transistor TR. A potential to be supplied to a well region is supplied to the anode of the photodiode PD. The anode of the photodiode PD and the well region are electrically connected to a reference potential, for example, a ground potential. The photodiode PD is disposed in the well region connected to the reference potential line. The drain of the transfer transistor TR is electrically connected to the FD, and the gate of the transfer transistor TR is electrically connected to the corresponding drive line 24.

The FDs of the four sensor units 12 that share one readout circuit 22 are electrically connected to each other and are electrically connected to an input end of the readout circuit 22. The readout circuit 22 includes, for example, a reset transistor RES, a selection transistor SEL, and the amplification transistor AMP. The selection transistor SEL can be omitted as needed.

The source, which is an input end of the readout circuit 22, of the reset transistor RES is electrically connected to the FD. The drain of the reset transistor RES is electrically connected to a power supply line (SVDD). The drain of the amplification transistor AMP is electrically connected to the power supply line (SVDD). The gate of the reset transistor RES is electrically connected to the corresponding drive line 24. The source of the amplification transistor AMP is electrically connected to the drain of the selection transistor SEL, and the gate of the amplification transistor AMP is electrically connected to the source of the reset transistor RES. The source, which is an output end of the readout circuits 22, of the selection transistor SEL is electrically connected to the corresponding output line 25, and the gate of the selection transistor SEL is electrically connected to the corresponding drive line 24.

When the transfer transistor TR is turned on to a conductive state, the transfer transistor TR transfers the electric charge from the photodiode PD to the FD. The reset transistor RES resets the potential of the FD to a predetermined potential. When the reset transistor RES is turned on, the reset transistor RES resets the potential of the FD to the potential of the power supply line (SVDD). The selection transistor SEL controls timing of outputting a signal from the readout circuit 22. The amplification transistor AMP generates a signal of voltage corresponding to the level of the electric charge held in the FD. The amplification transistor AMP, which is included in a source follower amplifier, outputs a pixel signal of voltage based on the level of the electric charge generated in the photodiode PD. When the selection transistor SEL is turned on, the amplification transistor AMP amplifies the potential of the FD and outputs voltage based on the potential to the column signal processing circuit 34 via the output line 25. The transfer transistor TR, the reset transistor RES, the amplification transistor AMP, and the selection transistor SEL are, for example, complementary metal-oxide-semiconductor (CMOS) transistors.

The selection transistor SEL can be disposed between the power supply line (SVDD) and the amplification transistor AMP. In this case, the drain of the reset transistor RES is electrically connected to the power supply line (SVDD) and the selection transistor SEL. The source, which is an output end of the readout circuit 22, of the amplification transistor AMP is electrically connected to the corresponding output line 25. A switch to change a capacitance value of the FD can also be disposed on an electrical path between the reset transistor RES and the second FD node FD2.

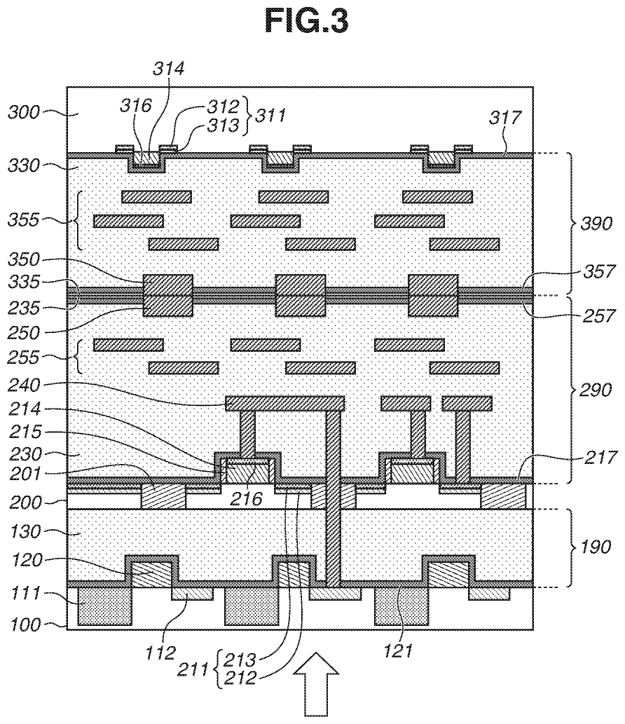

FIG. 3 is a schematic cross-sectional view of the photoelectric conversion apparatus according to the present exemplary embodiment. This cross-sectional view illustrates a cross-section of the photoelectric conversion apparatus taken along a line that passes through the photodiode PD and the gate of the transfer transistor TR in the first member 10, the second member 20, and the third member 30.

The lower side of FIG. 3 corresponds to a light-incident surface side, and the upper side of FIG. 3 is the opposite side of the light-incident surface side. Since FIG. 3 is a diagram illustrating a configuration example of a backside irradiation (BSI) type, the light-incident surface side (lower side) may be referred to as a back surface side and the opposite side (upper side) of the light-incident surface side may be referred to as a front surface side.

The photoelectric conversion apparatus according to the present exemplary embodiment includes the first semiconductor layer 100, the second semiconductor layer 200, and the third semiconductor layer 300. A first wiring structure 190 is disposed between the first semiconductor layer 100 and the second semiconductor layer 200. A second wiring structure 290 and a third wiring structure 390 are disposed between the second semiconductor layer 200 and the third semiconductor layer 300.

The first semiconductor layer 100 including the sensor region 13 includes photoelectric conversion units 111 and FDs 112. Each of the photoelectric conversion units 111 includes a semiconductor region of a first conductivity type, for example, n-type, generates signal charges, for example, electrons, and accumulates the signal charges. A region surrounding the photoelectric conversion unit 111 includes a semiconductor region of a second conductivity type, for example, p-type. Accordingly, the semiconductor region of the first conductivity type that forms the photoelectric conversion unit 111 and the semiconductor region of the second conductivity type form a PN junction diode. Each of the FDs 112 includes a semiconductor region of the first conductivity type, i.e., n-type.

On the first semiconductor layer 100, gate electrodes 120 of the transfer transistors TR are disposed to transfer electric charges accumulated in the photoelectric conversion units 111 to the corresponding FD 112. When a predetermined voltage is applied to the gate electrode 120, a channel region is formed, and the signal charge is transferred from the photoelectric conversion unit 111 to the FD 112. The photoelectric conversion units 111 are isolated from each other with an isolation unit (not illustrated). The isolation unit has the function of electrically isolating the photoelectric conversion units 111 from each other. The isolation unit can include an insulating part made of silicon oxide or the like. Typically, the isolation unit is formed using local oxidation of silicon (LOCOS), shallow trench isolation (STI), deep trench isolation (DTI), or the like. The isolation unit can include a semiconductor region that forms a potential barrier. Typically, the semiconductor region is a semiconductor region in which an electric charge having a polarity opposite to that of a signal charge accumulated in the photoelectric conversion unit 111 is a main carrier. Specifically, the semiconductor region is a semiconductor region of the second conductivity type, i.e., p-type, and the photoelectric conversion unit 111 and the semiconductor region of the second conductivity type form a PN junction.

While FIG. 2 illustrates the configuration in which the four sensor units 12 are connected to one amplification transistor AMP, FIG. 3 illustrates the cross-sectional view of the configuration of FIG. 2 in a simplified manner as needed.

A first diffusion prevention layer 121 that prevents diffusion of an elemental metal is disposed on the photoelectric conversion unit 111, the FD 112, and the gate electrode 120. The first diffusion prevention layer 121 has the effect of preventing diffusion of a metal element from the second semiconductor layer 200 and the third semiconductor layer 300 to the first semiconductor layer 100. The metal element included in the second semiconductor layer 200 and the third semiconductor layer 300 will be described below. The first diffusion prevention layer 121 is made of, for example, a silicon nitride (SiN), a silicon oxynitride (SiON), or a silicon carbide (SiC). Typically, the first diffusion prevention layer 121 is made of a silicon nitride. While The first diffusion prevention layer 121 is disposed on the FD 112, a contact electrode is disposed to be in contact with the FD 112, and thus a part of the first diffusion prevention layer 121 disposed on the FD 112 is removed.

The second semiconductor layer 200 is disposed on the first semiconductor layer 100, and an insulating film 130 is disposed between the front surface of the first semiconductor layer 100 and the back surface of the second semiconductor layer 200. The insulating film 130 is a part of the first wiring structure 190. The insulating film 130 is made of, for example, a silicon oxide (SiO).

Element isolation regions 201 made of a silicon monoxide (SiO) or the like are disposed in the second semiconductor layer 200. The readout circuits 22 are disposed in the second semiconductor layer 200. As described above, each of the readout circuits 22 includes, for example, the reset transistor RES, the selection transistor SEL, and the amplification transistor AMP. The first semiconductor layer 100 and the second semiconductor layer 200 are bonded in a state where the front surface of the first semiconductor layer 100 and the back surface of the second semiconductor layer 200 face each other. In other words, the first semiconductor layer 100 and the second semiconductor layer 200 are bonded in a face-to-back manner. A source/drain region 211 of each of the transistors disposed in the second semiconductor layer 200 includes an impurity diffusion region 212 and a low-resistance region 213. The low-resistance region 213 is a silicide structure formed using the salicide process.

The salicide process includes (a) forming a film including a metal element on a semiconductor layer, (b) performing a silicidation process, and (c) removing the metal element. First, a film including a metal element is formed on the surface of a semiconductor layer by a physical vapor deposition (PVD) method or the like. Next, the semiconductor layer is heated, so that the metal element on the semiconductor layer reacts and a silicide is formed. A region other than the semiconductor layer, for example, a metal film disposed on an insulating film, such as a silicon oxide film, is not subjected to the silicidation process, and thus the metal film remains as it is. Next, solution treatment is performed to selectively remove the metal film formed on the insulating film. With this process, on the gate, source, and drain regions of a transistor without an insulating film, a silicide remains. Since a silicide is formed in a self-aligned manner as described above, this process is called the “salicide process”.

If the semiconductor region serving as the source or drain region and the metal, such as the contact electrode, are heated in a state where the semiconductor region and the metal are in contact with each other, the contact portion between the semiconductor region and the metal may be silicided. In this case, the silicide is in contact with the metal, but is not in contact with the insulating film. In the present specification, a silicide formed in this process is not included in a salicide structure and a silicide structure.

The metal element forming the silicide structure is, for example, at least one selected from the group consisting of titanium, nickel, cobalt, tungsten, molybdenum, tantalum, chromium, palladium, and platinum, or an alloy including primarily of any of these. For example, the silicide structure on the source/drain region 211 of each of the transistors disposed in the second semiconductor layer 200 is a cobalt silicide, and the metal element forming the silicide structure is cobalt.

A second diffusion prevention layer 217 covering the source/drain region 211 and a gate electrode 214 of each of the transistors disposed in the second semiconductor layer 200 is disposed. The second diffusion prevention layer 217 has the effect of preventing diffusion of the metal element included in the low-resistance region 213. The second diffusion prevention layer 217 is made of, for example, a silicon nitride (SiN), a silicon oxynitride (SiON), or a silicon carbide (SiC).

In the present exemplary embodiment, the first semiconductor layer 100 and the second semiconductor layer 200 are bonded in a face-to-back manner. In a case of a configuration in which the first semiconductor layer 100 and the second semiconductor layer 200 are bonded in a face-to-face manner, the distance between the low-resistance region 213 disposed in the second semiconductor layer 200 and the photoelectric conversion units 111 is small. In this case, it is highly likely that the metal element in the silicide structure formed in the low-resistance region 213 can diffuse to the photoelectric conversion unit 111 and become noise components in the photoelectric conversion unit 111. On the other hand, in a case of the configuration in which the first semiconductor layer 100 and the second semiconductor layer 200 are bonded in a face-to-back manner, the distance between the low-resistance region 213 and the photoelectric conversion unit 111 is long. Accordingly, the metal element in the silicide structure formed in the low-resistance region 213 can hardly diffuse to the photoelectric conversion unit 111, and thus it is less likely to cause noise components in the photoelectric conversion unit 111. Accordingly, in the present exemplary embodiment, the configuration in which the first semiconductor layer 100 and the second semiconductor layer 200 are bonded in a face-to-back manner is adopted.

Insulating films 230 and 330 are disposed between the front surface of the second semiconductor layer 200 and the front surface of the third semiconductor layer 300. The insulating film 230 is a part of the second wiring structure 290, and the insulating film 330 is a part of the third wiring structure 390. The insulating films 230 and 330 are made of, for example, a silicon monoxide (SiO).

Transistors forming the logic circuit are disposed in the third semiconductor layer 300.

The second semiconductor layer 200 and the third semiconductor layer 300 are bonded in a state where the front surface of the second semiconductor layer 200 and the front surface of the third semiconductor layer 300 face each other. In other words, the second semiconductor layer 200 and the third semiconductor layer are bonded in a face-to-face manner.

Transistors disposed in the third semiconductor layer 300 is smaller than the transistors disposed in the second semiconductor layer 200. As described above, the transistors disposed in the third semiconductor layer 300 form the logic circuit. The logic circuit includes, for example, the vertical scanning circuits 42, the column signal processing circuits 34, and the horizontal scanning circuits 35. The column signal processing circuits 34 includes, for example, an AD conversion circuit. A source/drain region 311 of each of the transistors disposed in the third semiconductor layer 300 includes an impurity diffusion region 312 and a low-resistance regions 313 and 316. The low-resistance regions 313 and 316 have a silicide structure formed using the salicide process. The metal element forming the silicide structure is, for example, at least one selected from the group consisting of titanium, nickel, cobalt, tungsten, molybdenum, tantalum, chromium, palladium, and platinum, or an alloy composed primarily of any of these. For example, the silicide structure on the source/drain region 211 of each if the transistors disposed in the third semiconductor layer 200 is a nickel silicide, and the metal element forming the silicide structure is nickel. In other words, the metal element forming the silicide structure of each of the transistors disposed in the second semiconductor layer 200 is different from the metal element forming the silicide structure of each of the transistors disposed in the third semiconductor layer 300. This is because each of the transistors disposed in the third semiconductor layer 300 is smaller than each of the transistors disposed in the second semiconductor layer 200. Due to the difference in the size of the transistors, the metal element used in the third semiconductor layer 300 is different from the element metal used in the second semiconductor layer 200.

A third diffusion prevention layer 317 covering the source/drain region 311 and a gate electrode 314 of each of the transistors disposed in the third semiconductor layer 300 is disposed. The third diffusion prevention layer 317 has the effect of preventing diffusion of the metal element included in the low-resistance regions 313 and 316. The third diffusion prevention layer 317 is made of, for example, a silicon nitride (SiN), a silicon oxynitride (SiON), or a silicon carbide (SiC).

Fourth diffusion prevention layers 257 and 357 are disposed between the insulating film 230 included in the second member 20 and the insulating film 330 included in the third member 30. The fourth diffusion prevention layers 257 and 357 have the effect of preventing diffusion of the metal element included in the low-resistance regions 313 and 316. The fourth diffusion prevention layers 257 and 357 are each made of, for example, a silicon carbide (SiC).

In the first member 10, a conductor 240 is disposed as the first wiring structure 190 in the insulating film 130, the element isolation region 201, and the insulating film 230. The conductor 240 is a through-wiring line that passes through the insulating film 130 and the element isolation region 201. The conductor 240 is a wire that connects each of the FDs 112 disposed in the first semiconductor layer 100 to the gate of the amplification transistor AMP disposed on the second semiconductor layer 200. Although not illustrated, the through-wiring line that passes through the insulating film 130 and the element isolation region 201 is also electrically connected to the second semiconductor region that forms the PN junction with the first semiconductor region of the photoelectric conversion unit 111.

In the second member 20, conductors 255 in a plurality of layers in the insulating film 230 is disposed as the second wiring structure 290. The conductors 255 are, for example, wires serving as the drive lines 24 and the output lines 25. Conductors 250 are disposed in an uppermost layer of the insulating film 230.

In the third member 30, conductors 355 in a plurality of layers in the insulating film 330 are disposed as the third wiring structure 390, and conductors 350 are disposed in an uppermost layer of the insulating film 330. The conductors 250 exposed at the surface of the second member 20 and the conductors 350 exposed at the surface of the third member 30 are joined together with a metal junction.

The conductors 250 and 350 are composed primarily of copper, for example. An insulating film 235 disposed as an uppermost layer of the second member 20 and an insulating film 335 disposed as an uppermost layer of the third member 30 are joined together by covalent bonding between the insulating films. In other words, the second member 20 and the third member 30 are joined together with a so-called hybrid bonding. The insulating films 235 and 335 are, for example, a silicon oxide film. Alternatively, the insulating films 235 and 335 can be a silicon oxynitride film, a silicon nitride film, or a stacked structure of such insulating films including a silicon oxide film.

The conductors in the first member 10, the second member 20, and the third member 30 are composed primarily of a metal material, such as copper, aluminum, or tungsten. A barrier metal to prevent diffusion of metal, such as copper or tungsten, can also be disposed between the insulating films and the conductors. Because of the combination of the insulating films and the conductors as described above, the first member 10, the second member 20, and the third member 30 are electrically connected to each other.

Although not illustrated, an optical structure, such as a color filter layer, a microlens, or the like can be disposed on the backside (light irradiation type) of the first semiconductor layer 100. Another microlens, such as an inner-layer lens, can also be disposed between the microlens and the first semiconductor layer 100. A fixed charge film (not illustrated) can also be disposed on the back surface of the first semiconductor layer 100 to reduce dark current. Examples of a negative fixed charge film include a hafnium oxide (HfO₂) film, an aluminum oxide (Al₂O₃) film, a zirconium oxide (ZrO₂) film, a tantalum oxide (Ta₂O₅) film, and a titanium oxide (TiO₂) film. Further, a conductor can be disposed between color filter layers or between a color filter layer and the first semiconductor layer 100 to prevent optical crosstalk between pixels. In a planar view, conductors can be disposed discretely, or conductors in a mesh shape or a lattice shape can be disposed.

### (Manufacturing Method)

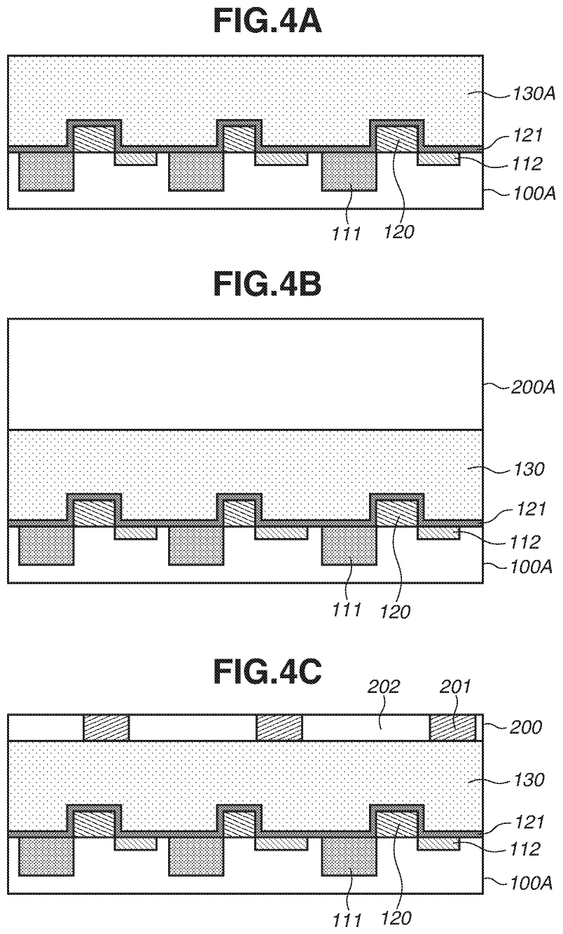

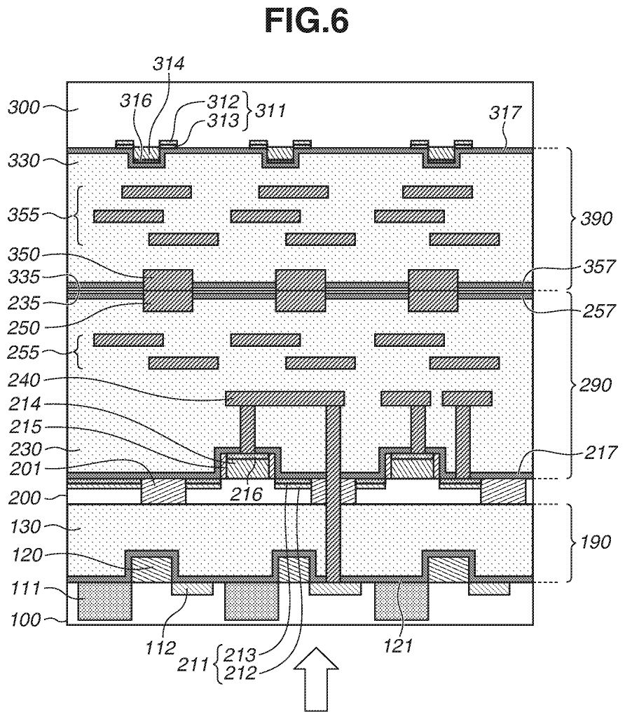

Next, a manufacturing method of the photoelectric conversion apparatus according to the present exemplary embodiment will be described with reference to FIGS. 4A to 4C and FIG. 6.

A first semiconductor layer 100A illustrated in FIG. 4A is, for example, a silicon substrate and includes the photoelectric conversion units 111 and the FDs 112. An element isolation region (not illustrated) formed of an insulating material can also be formed on the first semiconductor layer 100A. In the first semiconductor layer 100A, the gate electrode 120 of the transfer transistor TR is formed, and then the first diffusion prevention layer 121 that is made of, for example, a silicon nitride, is formed. After that, an insulating film 130A formed of a silicon oxide film is formed on the first semiconductor layer 100A.

Next, as illustrated in FIG. 4B, a second semiconductor layer 200A is formed on the insulating film 130.

In the present exemplary embodiment, for example, the first semiconductor layer 100A and the second semiconductor layer 200A can be joined together with a silicon oxide film. Specifically, the silicon oxide film is formed on the back surface of the second semiconductor layer 200A, and the back surface of the second semiconductor layer 200A and the front surface of the first semiconductor layer 100A are joined together in a face-to-face manner.

Next, as illustrated in FIG. 4C, the second semiconductor layer 200A is thinned to form the second semiconductor layer 200. After that, a part of the second semiconductor layer 200 is removed by etching, and an insulating film is embedded to form the element isolation regions 201. The element isolation regions 201 electrically isolate well regions 202 for the reset transistor RES, the amplification transistor AMP, and the selection transistor SEL, and FD capacity switching transistors and the like, which are disposed in the second semiconductor layer 200. The well regions 202 are, for example, a semiconductor region of the second conductivity type. i.e., p-type.

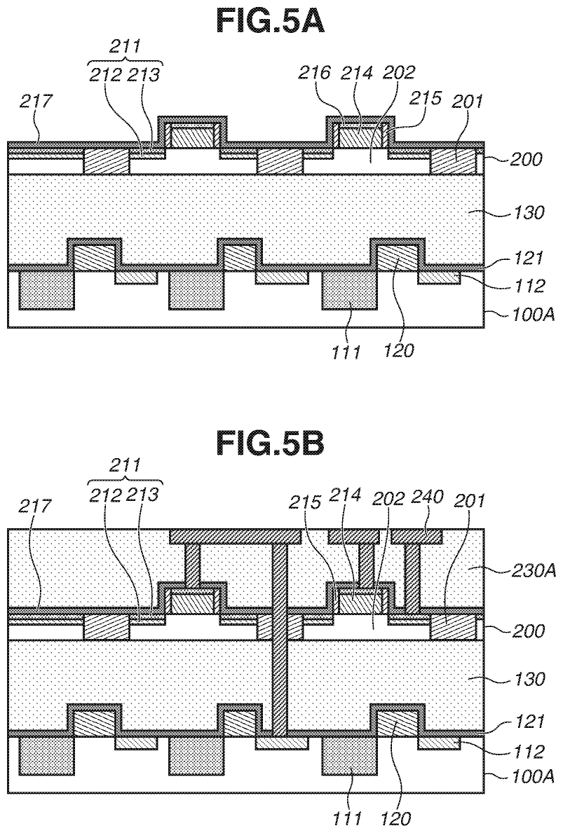

Next, as illustrated in FIG. 5A, the gate electrodes 214 of the transistors and side walls 215 are formed by a photolithography technique and an etching technique. The gate electrodes 214 are made of polysilicon, for example. The side walls 215 are made of a silicon nitride, for example. After the gate electrodes 214 and the side walls 215 are formed, the impurity diffusion regions 212 of the source/drain regions 211 is formed by an ion implantation technique and a plasma doping technique. The impurity diffusion regions 212 are, for example, a semiconductor region of the first conductivity type, i.e., n-type. Next, the low-resistance regions 213 having a silicide structure is formed using the salicide process. The second diffusion prevention layer 217 that is made of a silicon nitride, for example, is formed. In this process, a low-resistance region 216 can also be formed on the gate electrode 214.

In one embodiment, the second diffusion prevention layer 217 is directly formed in contact with the low-resistance regions 213, because the configuration prevents diffusion of the metal element included in the low-resistance region 213. To prevent diffusion of the metal element, in one embodiment, the second diffusion prevention layer 217 is larger than the low-resistance region 213 to cover the low-resistance region 213 as viewed from above.

Next, as illustrated in FIG. 5B, an insulating film 230A is formed on the second semiconductor layer 200. After that, an opening process is performed on the insulating film 230A to dispose conductors to connect the first semiconductor layer 100A, the gate electrodes 120, the second semiconductor layer 200, and the gate electrodes 214. These openings are via openings for through-wiring lines for connection to the FDs 112 and the gate electrodes 120. The via openings are embedded with metal, such as tungsten (W), to form the through-wiring line. A conductive member made of, for example, copper and aluminum is formed as appropriate to form the conductor 240. In the via opening process described above, the via openings for connection to the first semiconductor layer 100A and the gate electrode 120 are formed and the via openings are embedded with metal (a first opening process and a first embedding process). Next, the via openings for connection to the second semiconductor layer 200 and the gate electrode 214 are formed and the via openings are embedded with metal (a second opening process and a second embedding process). By the processes with the above described procedure, it is possible to prevent diffusion of the metal element from the low-resistance region 213 to the first semiconductor layer 100A. In the via opening process described above, the first diffusion prevention layer 121 and the second diffusion prevention layer 217 can be used as an etching stop layer. Alternatively, a layer different from the first diffusion prevention layer 121 and the second diffusion prevention layer 217 can be used as the etching stop layer.

Next, as illustrated in FIG. 6, after the conductors 255 and 250 have been formed in the insulating film 230, the third semiconductor layer 300 and the first semiconductor layer 100A having the second semiconductor layer 200 are stacked. As described above, the conductor 250 and the conductor 350 are stacked in a face-to-face manner, and the insulating film 230 and the insulating film 330 are stacked in a face-to-face manner. In other words, as described above, these members are bonded together with a so-called hybrid bonding, whereby the conductors 250 and the conductors 350 are electrically connected to each other. The second semiconductor layer 200 and the third semiconductor layer 300 can be bonded together not only with a hybrid bonding, but also by bonding the insulating films.

After the first semiconductor layer 100A and the third semiconductor layer 300 have been stacked, the first semiconductor layer 100A is thinned to form the first semiconductor layer 100. An optical structure, such as a color filter layer, a microlens, or an inner-layer lens, and a conductor for preventing optical crosstalk between pixels are formed on the first semiconductor layer 100.

In the present exemplary embodiment, the source regions or the drain regions of the transistors forming the readout circuit 22 disposed in the second semiconductor layer 200 have a salicide structure, whereby the resistance value is reduced. With this configuration, the photoelectric conversion apparatus capable of high-speed driving for the readout circuits 22 can be provided.

### Second Exemplary Embodiment

Descriptions of components of a second exemplary embodiment that are similar to those of the first exemplary embodiment are omitted, and only differences from the first exemplary embodiment will be described below.

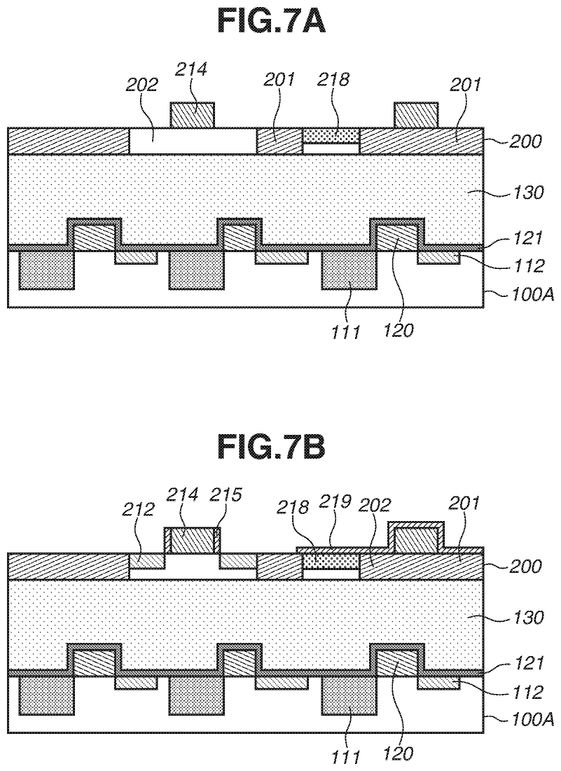

The second exemplary embodiment differs from the first exemplary embodiment in that the photoelectric conversion apparatus according to the second exemplary embodiment includes an element that does not have the low-resistance region formed by the salicide process in the second semiconductor layer 200. On the other hand, like in the configuration illustrated in FIGS. 4A to 4C according to the first exemplary embodiment, the second semiconductor layer 200A is thinned to form the second semiconductor layer 200, and the element isolation region 201 is formed. After that, an impurity diffusion region 218 serving as a resistor element or the like and the gate electrode 214 are formed. FIG. 7A illustrates a cross-sectional view of the photoelectric conversion apparatus in this state.

Next, as illustrated in FIG. 7B, the impurity diffusion region 212 serving as the source/drain region of the transistor is formed and an insulating film 219 is deposited. The insulating film 219 is patterned by etching to form the side wall 215. In this processing, the insulating film 219 is patterned such that the insulating film 219 remains on the element on which no low-resistance region is formed. An example of the element having no low-resistance region is a resistor element. Alternatively, some of the transistors that are used for the readout circuit 22 can include no low-resistance region.

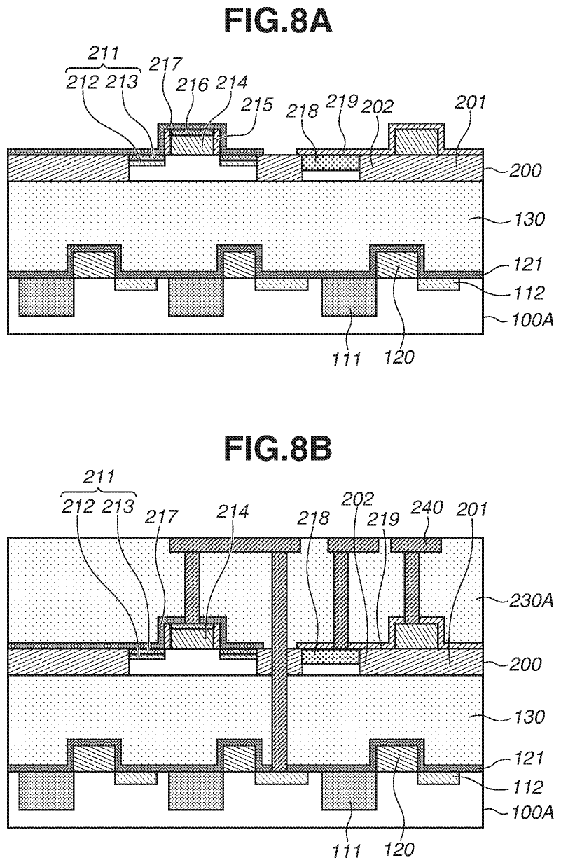

Next, as illustrated in FIG. 8A, the low-resistance region 213 formed of the silicide structure including the metal element is formed using the salicide process. After that, for example, a silicon nitride is deposited and patterned to form the second diffusion prevention layer 217.

Next, as illustrated in FIG. 8B, the insulating film 230A and the conductor 240 are formed. In this case, the first diffusion prevention layer 121, the second diffusion prevention layer 217, and the insulating film 219 can be used as an etching stop film during the via opening process. After that, like in the first exemplary embodiment, a conductor is further formed, the third semiconductor layer 300 is stacked, and an optical structure is formed.

According to the present exemplary embodiment, the source regions or the drain regions of the transistors forming the readout circuit 22 disposed in the second semiconductor layer 200 have the salicide structure, whereby the resistance value is reduced. With this configuration, the photoelectric conversion apparatus capable of high-speed driving in terms of the readout circuits 22 can be provided.

### Third Exemplary Embodiment

Descriptions of components of a third exemplary embodiment that are similar to those of the exemplary embodiments described above are omitted, and only differences from the above-described exemplary embodiments will be described below.

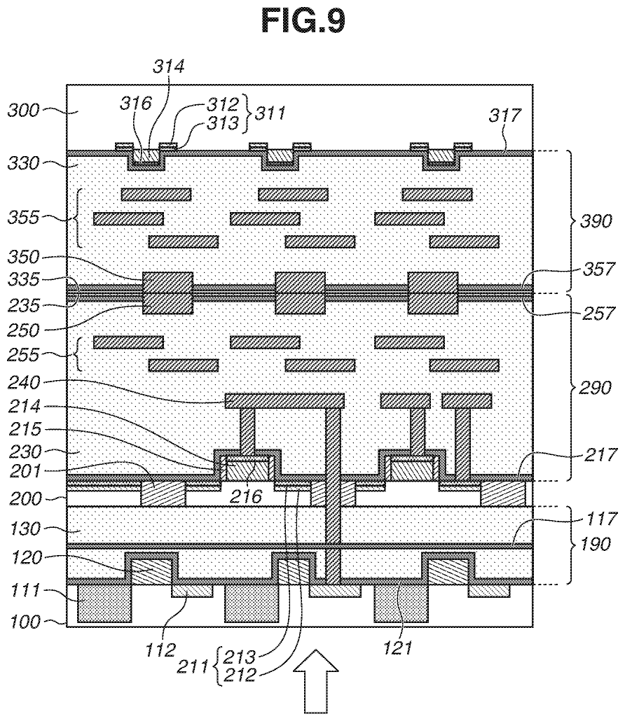

As illustrated in FIG. 9, the third exemplary embodiment differs from the other exemplary embodiments in that a fifth diffusion prevention layer 117 is disposed in the first wiring structure 190. The fifth diffusion prevention layer 117 is made of, for example, a silicon nitride (SiN), a silicon oxynitride (SiON), or a silicon carbide (SiC). A description will be given of a case where the insulating film 130 is made of a silicon monoxide (SiO) and the fifth diffusion prevention layer 117 is made of a silicon nitride. In this case, an opening for the conductor 240 serving as a through-wiring line is formed in both the insulating film 130 and the fifth diffusion prevention layer 117. The insulating film 130 and the fifth diffusion prevention layer 117 are made of materials different from each other and thus have different etching rates during etching. Accordingly, the fifth diffusion prevention layer 117 is thinned to some extent. For example, the thickness of the fifth diffusion prevention layer 117 is set to be smaller than the thickness of the first diffusion prevention layer 121. This configuration makes it possible to form an opening in each of the insulating film 130 and the fifth diffusion prevention layer 117 in the same process, which is advantageous.

According to the present exemplary embodiment, the source regions or the drain regions of the transistors forming each of the readout circuits 22 disposed in the second semiconductor layer 200 have the salicide structure, whereby the resistance value is reduced. According to this configuration, the photoelectric conversion apparatus capable of high-speed driving in terms of the readout circuits 22 can be provided.

### Fourth Exemplary Embodiment

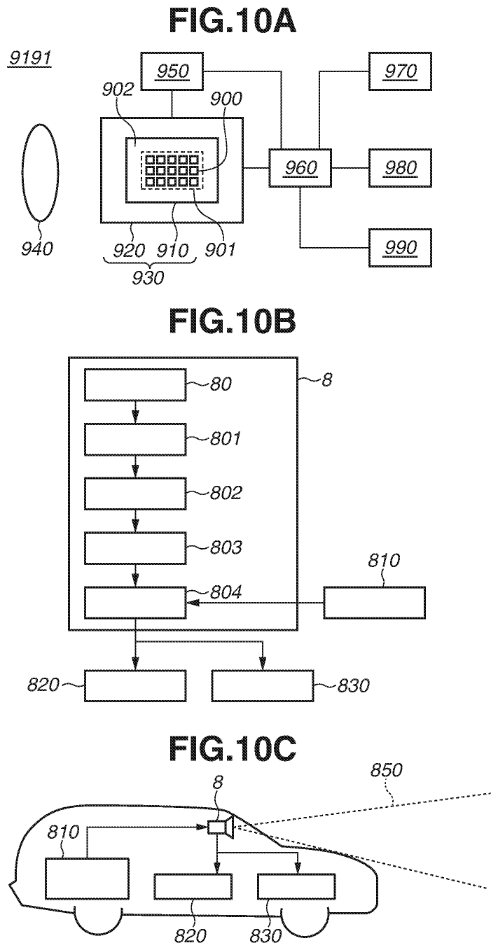

FIGS. 10A to 10C are diagrams illustrating an equipment according to a fourth exemplary embodiment. The fourth exemplary embodiment is applicable to any of the exemplary embodiments described above. FIG. 10A is a block diagram illustrating equipment 9191 including a semiconductor apparatus 930 according to the present exemplary embodiment. The photoelectric conversion apparatus according to any one of the exemplary embodiments can be used as the semiconductor apparatus 930. The equipment 9191 including the semiconductor apparatus 930 will be described in detail.

The semiconductor apparatus 930 can include not only a semiconductor device 910 including the first semiconductor layer 100, but also a package 920 that accommodates the semiconductor device 910. The package 920 can include a substrate on which the semiconductor device 910 is fixed, and a lid that is made of glass or the like and is opposed to the semiconductor device 910. The package 920 can further include a bonding member, such as a bonding wire and a bump, to connect a terminal disposed on the substrate with a terminal disposed on the semiconductor device 910.

The equipment 9191 includes at least any one of an optical device 940, a control device 950, a processing device (signal processing unit) 960, a display device 970, a storage device 980, and a mechanical device 990. The optical device 940 is adapted for the semiconductor apparatus 930. Examples of the optical device 940 include a lens, a shutter, and a mirror. The control device 950 controls the semiconductor apparatus 930. The control device 950 is, for example, a semiconductor device, such as an application-specific integrated circuit (ASIC).

The processing device 960 processes signals output from the semiconductor apparatus 930. The processing device 960 is a semiconductor device, such as a central processing unit (CPU) or an ASIC, that forms an analog front end (AFE) or a digital front end (DFE). The display device 970 is, for example, an electroluminescence (EL) display device or a liquid crystal display device, and displays information (images) obtained by the semiconductor apparatus 930. The storage device 980 is, for example, a magnetic device or a semiconductor device, and stores information (images) obtained by the semiconductor apparatus 930. The storage device 980 is a volatile memory, such as a static random-access memory (SRAM) or a dynamic RAM (DRAM), or a non-volatile memory, such as a flash memory or a hard disk drive.

The mechanical device 990 includes a drive unit or a propelling unit, such as a motor or an engine. The equipment 9191 displays signals output from the semiconductor apparatus 930 on the display device 970, and uses a communication device (not illustrated) included in the equipment 9191 to transmit the signals to the outside of the equipment 9191. Thus, in one embodiment, the equipment 9191 further includes the storage device 980 and the processing device 960, in addition to a storage circuit and an arithmetic circuit included in the semiconductor apparatus 930. The mechanical device 990 can be controlled based on signals output from the semiconductor apparatus 930.

The equipment 9191 is to be used as electronic equipment, such as an information terminal including an image capturing function (e.g., a smartphone or a wearable terminal), or a camera (e.g., an interchangeable lens camera, a compact camera, a video camera, or a monitoring camera). The mechanical device 990 in a camera drives components of the optical device 940 to perform zooming, focusing, or operating of the shutter. Alternatively, the mechanical device 990 in a camera moves the semiconductor apparatus 930 to perform vibration control.

The equipment 9191 can be used as transport equipment, such as a vehicle, a ship, or an aircraft. The mechanical device 990 in transport equipment can be used as a mobile apparatus. The equipment 9191 as transport equipment is suitable to transport the semiconductor apparatus 930 or to provide assistance and/or automation of driving (controlling) using the image capturing function. The processing device 960 for providing assistance and/or automation of driving (controlling) can perform processing for operating the mechanical device 990 as a mobile apparatus based on information obtained by the semiconductor apparatus 930. Alternatively, the equipment 9191 can be used as medical equipment, such as an endoscope, measurement equipment, such as a distance measurement sensor, an analyzer, such as an electron microscope, office equipment, such as a copying machine, or industrial equipment, such as a robot.

According to the exemplary embodiments described above, favorable pixel characteristics is obtainable. Thus, the value of the semiconductor apparatus 930 is increased. The advantage of “increasing the value” described here indicates at least any of addition of functions, improvement in performance, improvement in characteristics, improvement in reliability, improvement in manufacturing yield, reduction in environmental load, reduction in cost, reduction in size, and reduction in weight.

Accordingly, the use of the semiconductor apparatus 930 according to the present exemplary embodiment in the equipment 9191 also increases the value of the equipment 9191. For example, with the semiconductor apparatus 930 mounted on transport equipment, an excellent performance is obtainable in a case of capturing images outside the transport equipment or measuring the external environment, for example. Therefore, in manufacturing and sales of transport equipment, mounting the semiconductor apparatus 930 according to the present exemplary embodiment on the transport equipment is advantageous to enhancement of the performance of the transport equipment. The semiconductor apparatus 930 is particularly suitable for transport equipment in which driving assistance and/or automated driving of the transport equipment is provided using information obtained by the semiconductor apparatus 930.

A photoelectric conversion system and a moving body according to the present exemplary embodiment will be described with reference to FIGS. 10B and 10C.

FIG. 10B illustrates an example of a photoelectric conversion system for an on-vehicle camera. A photoelectric conversion system 8 includes a photoelectric conversion apparatus 80. The photoelectric conversion apparatus 80 is any one of the photoelectric conversion apparatuses according to the above-described exemplary embodiments. The photoelectric conversion system 8 includes an image processing unit 801 that performs image processing on a plurality of pieces of image data acquired by the photoelectric conversion apparatus 80, and a parallax acquisition unit 802 that calculates a parallax (phase difference between parallax images) based on the plurality of pieces of image data acquired by the photoelectric conversion system 8. The photoelectric conversion system 8 also includes a distance acquisition unit 803 that calculates a distance to a target object based on the calculated parallax, and a collision determination unit 804 that determines whether there is a possibility of collision based on the calculated distance. The parallax acquisition unit 802 and the distance acquisition unit 803 are examples of a distance information acquisition unit that acquires distance information indicating a distance to a target object. The distance information is information about a parallax, a defocus amount, a distance to a target object, and the like. The collision determination unit 804 can determine the possibility of collision using any one of the pieces of distance information. The distance information acquisition unit can be implemented by an exclusively designed hardware or software module. Alternatively, the distance information acquisition unit can be implemented by a field programmable gate array (FPGA), an ASIC, or the like, or a combination of the FPGA and the ASIC.

The photoelectric conversion system 8 is connected to a vehicle information acquisition device 810, and thus acquires vehicle information, such as a vehicle speed, a yaw rate, and a steering angle. The photoelectric conversion system 8 is also connected to a control engine control unit (ECU) 820 serving as a control device (control unit) that outputs a control signal for applying a braking force to a vehicle, based on the result of determination by the collision determination unit 804. The photoelectric conversion system 8 is also connected to an alarm device 830 that issues an alarm to a driver based on the result of determination by the collision determination unit 804. For example, in a case where there is a high possibility of collision based on the result of determination by the collision determination unit 804, the control ECU 820 performs vehicle control to avoid a collision or reduce damage by, for example, applying brakes, releasing an accelerator, or restraining engine power. The alarm device 830 warns a user by, for example, generating an alarm sound, displaying alarm information on a screen of a car navigation system or the like, or applying vibrations to a seat belt or a steering wheel.

In the present exemplary embodiment, the photoelectric conversion system 8 captures images of an area around the vehicle, such as the front or the rear of the vehicle.

FIG. 10C illustrates the photoelectric conversion system 8 in a case where an image of the front of the vehicle (an imaging range 850) is captured. The vehicle information acquisition device 810 sends an instruction to the photoelectric conversion system 8 or the photoelectric conversion apparatus 80. This configuration further improves the accuracy of ranging.

While the example of control for avoiding a collision with another vehicle is described above, the present exemplary embodiment is also applicable to control for automated driving to follow another vehicle, control for automated driving not to stray from a traffic lane, and the like. The photoelectric conversion system 8 is not limited to a vehicle, such as an automobile, and is also applicable to, for example, a moving body (mobile apparatus), such as a ship, an airplane, or an industrial robot. The photoelectric conversion system 8 is applicable not only to a moving body, but also to equipment that widely performs object recognition, such as an intelligent transport system (ITS).

### Modified Examples

The disclosure is not limited to the above-described exemplary embodiments and can be modified in various ways.

For example, an example in which a part of the configuration according to any of the exemplary embodiments is added to any of the other exemplary embodiments, and an example in which a part of the configuration according to any of the exemplary embodiments is replaced with a part of the configuration according to any of the other exemplary embodiments are also included in the exemplary embodiments of the disclosure.

The equipment 9191 (photoelectric conversion system) described above in the exemplary embodiment is an example of the photoelectric conversion system to which the photoelectric conversion apparatuses according to the above-described exemplary embodiments is applicable, and the photoelectric conversion system to which the photoelectric conversion apparatuses according to the above-described exemplary embodiments is applicable is not limited only to the configuration illustrated in FIGS. 10A to 10C.

The disclosure is not limited to the above-described exemplary embodiments and can be modified in various ways. For example, an example where a part of the configuration according to any of the exemplary embodiments is added to any of the other exemplary embodiments, and an example where a part of the configuration according to any of the exemplary embodiments is replaced with a part of the configuration according to any of the other exemplary embodiments are also included in the exemplary embodiments of the disclosure. The disclosure of the present specification is not limited to what is explicitly described in the present specification, and includes all the matter that can be grasped from the present specification and the drawings attached to the present specification.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-122765, filed Aug. 1, 2022, which is hereby incorporated by reference herein in its entirety.

What is claimed is:

1. A photoelectric conversion apparatus comprising:
a first member including a photoelectric conversion unit and a transfer transistor in a first semiconductor layer, the transfer transistor being configured to transfer an electric charge generated in the photoelectric conversion unit;
a second member including a readout circuit in a second semiconductor layer, the readout circuit being configured to output a signal based on the electric charge transferred from the transfer transistor; and
a third member including a signal processing circuit in a third semiconductor layer, the signal processing circuit being configured to process the signal,
wherein a first wiring structure included in the first member is disposed between the first semiconductor layer and the second semiconductor layer, and a second wiring structure included in the second member and a third wiring structure included in the third member are stacked between the second semiconductor layer and the third semiconductor layer,
wherein the readout circuit is configured to output the signal from the second member to the third member via an output line disposed in the second wiring structure,
wherein a source region or a drain region of a transistor forming the readout circuit includes a salicide structure, and
wherein a diffusion prevention layer is disposed between the first semiconductor layer and the second semiconductor layer, the diffusion prevention layer preventing diffusion of metal included in the salicide structure.

2. A photoelectric conversion apparatus comprising:
a first member including a photoelectric conversion unit and a transfer transistor in a first semiconductor layer, the transfer transistor being configured to transfer an electric charge generated in the photoelectric conversion unit;
a second member including a readout circuit in a second semiconductor layer, the readout circuit being configured to output a signal based on the electric charge transferred from the transfer transistor; and
a third member including a signal processing circuit in a third semiconductor layer, the signal processing circuit being configured to process the signal,
wherein a first wiring structure included in the first member is disposed between the first semiconductor layer and the second semiconductor layer, and a second wiring structure included in the second member and a third wiring structure included in the third member are stacked between the second semiconductor layer and the third semiconductor layer,
wherein the readout circuit is configured to output a signal from the second member to the third member via an output line disposed in the second wiring structure,
wherein a source region or a drain region of a transistor forming the readout circuit includes a silicide structure, the silicide structure being in contact with an insulating film included in the second wiring structure, and
wherein a diffusion prevention layer is disposed between the first semiconductor layer and the second semiconductor layer, the diffusion prevention layer preventing diffusion of metal included in the silicide structure.

3. The photoelectric conversion apparatus according to claim 1, wherein the transistor is one of a reset transistor, a selection transistor, and an amplification transistor.

4. The photoelectric conversion apparatus according to claim 2, wherein the transistor is one of a reset transistor, a selection transistor, and an amplification transistor.

5. The photoelectric conversion apparatus according to claim 1, wherein a gate of the transistor includes the salicide structure.

6. The photoelectric conversion apparatus according to claim 2, wherein a gate of the transistor includes the silicide structure, and the silicide structure included in the gate is in contact with the insulating film included in the second wiring structure.

7. The photoelectric conversion apparatus according to claim 1, wherein the salicide structure is disposed between the second semiconductor layer and the third semiconductor layer.

8. The photoelectric conversion apparatus according to claim 2, wherein the silicide structure is disposed between the second semiconductor layer and the third semiconductor layer.

9. The photoelectric conversion apparatus according to claim 1, wherein the first member and the second member are electrically connected with a through-wiring line passing through an insulator included in the second semiconductor layer and an insulating layer included in the first wiring structure.

10. The photoelectric conversion apparatus according to claim 2, wherein the first member and the second member are electrically connected with a through-wiring line passing through an insulator included in the second semiconductor layer and an insulating layer included in the first wiring structure.

11. The photoelectric conversion apparatus according to claim 1, wherein another diffusion prevention layer to prevent diffusion of metal included in the salicide structure is disposed between the second semiconductor layer and the second wiring structure.

12. The photoelectric conversion apparatus according to claim 2, wherein another diffusion prevention layer to prevent diffusion of metal included in the silicide structure is disposed between the second semiconductor layer and the second wiring structure.

13. The photoelectric conversion apparatus according to claim 1, wherein the diffusion prevention layer includes any one of silicon nitride, silicon oxynitride, and silicon carbide.

14. The photoelectric conversion apparatus according to claim 2, wherein the diffusion prevention layer includes any one of silicon nitride, silicon oxynitride, and silicon carbide.

15. The photoelectric conversion apparatus according to claim 11, wherein the another diffusion prevention layer includes any one of silicon nitride, silicon oxynitride, and silicon carbide.

16. The photoelectric conversion apparatus according to claim 12, wherein the another diffusion prevention layer includes any one of silicon nitride, silicon oxynitride, and silicon carbide.

17. The photoelectric conversion apparatus according to claim 1, wherein a diffusion region is formed in the second semiconductor layer, and a silicide structure is not formed in the diffusion region.

18. The photoelectric conversion apparatus according to claim 2, wherein a diffusion region is formed in the second semiconductor layer, and a silicide structure is not formed in the diffusion region.

19. The photoelectric conversion apparatus according to claim 1, wherein at least one of a source region, a drain region, and a gate of a transistor forming the signal processing circuit includes a salicide structure.

20. The photoelectric conversion apparatus according to claim 2, wherein at least one of a source region, a drain region, and a gate of a transistor forming the signal processing circuit includes a silicide structure.

21. The photoelectric conversion apparatus according to claim 19, wherein a metal element included in the salicide structure included in the transistor forming the readout circuit is different from a metal element included in the salicide structure included in the transistor forming the signal processing circuit.

22. The photoelectric conversion apparatus according to claim 20, wherein a metal element included in a silicide structure included in the transistor forming the readout circuit is different from a metal element included in the silicide structure included in the transistor forming the signal processing circuit.

23. Equipment comprising:
the photoelectric conversion apparatus according to claim 1; and
at least any one of
an optical device adapted to the photoelectric conversion apparatus;
a control device configured to control the photoelectric conversion apparatus;
a processing device configured to process a signal output from the photoelectric conversion apparatus;
a display device configured to display information obtained by the photoelectric conversion apparatus;
a storage device configured to store information obtained by the photoelectric conversion apparatus; and
a mechanical device configured to operate based on information obtained by the photoelectric conversion apparatus.

24. A manufacturing method of a photoelectric conversion apparatus, comprising:
preparing a member including a photoelectric conversion unit disposed in a first semiconductor layer, a transfer transistor configured to transfer an electric charge generated in the photoelectric conversion unit, and an insulating film disposed on the photoelectric conversion unit and the transfer transistor;
stacking the member and a second semiconductor layer;
forming a readout circuit in the second semiconductor layer, the readout circuit being configured to output a signal based on the electric charge transferred from the transfer transistor;
forming a silicide in a source region or a drain region of a transistor forming the readout circuit, and forming an insulating film on the silicide;
forming a first wiring structure between the first semiconductor layer and the second semiconductor layer;
forming a second wiring structure on the second semiconductor layer;
forming a signal processing circuit in a third semiconductor layer, the signal processing circuit being configured to process the signal;
forming a third wiring structure on the third semiconductor layer; and
stacking the second semiconductor layer and the third semiconductor layer in such a manner that the second wiring structure and the third wiring structure face each other,
wherein the readout circuit is configured to output the signal via an output line disposed in the second wiring structure.
